(19) United States
(12) Patent Application Publication
(10) Pub. No.: US 2005/0205292 A1
(43) Pub. Date: Sep. 22, 2005

(54) Circuit and method for broadband switching noise suppression in multilayer printed circuit boards using localized lattice structures

(75) Inventors: Shawn D. Rogers, Jessup, MD (US); Todd Steigerwald, Austin, TX (US)

Correspondence Address: Brinks Hofer Gilson & Lione, P.O. Box 10395, Chicago, IL, 60610, US

(73) Assignee: Etenna Corporation.

(21) Appl. No.: 10/803,311

(22) Filed: Mar. 18, 2004

(51) Int. Cl. H05K 7/06

(52) U.S. Cl. 174/255; 174/260; 174/262

(57) ABSTRACT

An apparatus for suppressing noise in an electronic device includes a multiple layer structure in which localized arrays of chip capacitors and/or patches around sources of electromagnetic waves are used. The PCB includes multiple conductive layers at different potentials, dielectric layers separating the conductive layers, conductive rods extending between at least two of the conductive layers, and a layer of patches disposed adjacent or on one or more of the conductive layers. The conductive rods are connected to one of the conductive layers and chip capacitors connect the conductive rods to another of the conductive layers. A particular location can be effectively isolated from noise using a few unit cells of an array of patches/capacitors partially or completely surrounding the particular location.

### BACKGROUND

This invention is related generally to reduction of noise induced in power planes due to switching of digital circuits. More particularly, the present invention is related to circuits and methods for suppression of transverse electromagnetic modes in parallel plate waveguides.

A common problem in electronic systems is switching noise induced in the power distribution system by switching of digital circuits of the system. Conventionally, such a system has one or more power planes designated, for example, +Vcc, and one or more ground planes. The potential difference between the power plane and the ground plane provides operating voltage for the circuits of the system. If the system includes digital or other circuits with fast-switching outputs, noise can be induced in the power planes and even in the ground plane. Another noise mechanism is the internal short-circuit current that occurs within the digital circuits, which can reach several Amperes producing low impedance—high impulse transitions of various frequencies which progress through the power planes. The noise may have several sources, but generally is due to the high slew rate of the digital output and the non-zero inductance of the power plane. Especially for an output driving a large capacitive load, the L(di/dt) noise can be substantial. This noise on the power plane can affect other circuits, slowing system operation or producing data errors. The problem occurs in all types of systems, including integrated circuits and circuits formed on printed circuit boards (PCBs).

One of the techniques to mitigate power plane noise induced by digital switching is to use radio frequency (RF) bypass capacitors between +Vcc and ground layers. Other techniques use a very thin high dielectric constant material, low impedance, parallel-plate waveguides for power distribution, or split power planes which meet at only one common point.

Discrete board-mounted bypass capacitors are the standard RF noise decoupling approach. The idea of this approach is to provide a low reactance path between power and ground to decouple RF signals from the power terminal of a switching device such as a digital IC. To this end, discrete capacitors of widely different values (lower values have less parasitic inductance) are placed as close as possible to the power pins of integrated circuits.

Depending on the application, this approach is often adequate to reduce the power plane noise problem to an acceptable level. Chip capacitors are relatively inexpensive to add to a PCB design. However, detriments exist to merely using individual isolated capacitors to solve the power plane noise problems. For example, such capacitors have practical high frequency limits of about 1 GHz or less due to the parasitic series inductance of vias used to connect the bypass capacitor between +Vcc and ground layers. Also, the self inductance inherent in the capacitors reduces the high frequency limit of operation.

The use of very thin (˜2 mil) dielectric cores, such as Nelco 4000-13 BC or ZBC 2000™ from Merix Corp., Forest Grove, Oreg., to separate power and ground planes help to decouple RF signals so that a number of decoupling capacitors may be eliminated. This approach is called a buried capacitor (or C-plane) layer. The C-plane works by supplying enough charge to the chips so that the input voltage will not drop with increasing current demand from the chips. However, such an approach will not suppress the parasitic resonance of parallel plate modes because it will not cut off transverse electromagnetic (TEM) modes. For example, high speed signal vias passing through the C-plane will induce electromagnetic waves within the parallel plates that will propagate. This phenomenon happens regardless of how much charge the C-plane can supply. In the case of supplying charge to chips, the C-plane is limited in response speed by the dielectric used and essentially does not operate at frequencies exceeding about 2 GHz.

A reference parallel plate waveguide (Kamgaing, 2002) includes a buried metal layer that is separated from the overlying metal surface by a dielectric layer. The buried layer contains patches that extend over the entire area of the overlying surface. The overall thickness of the disclosed parallel plate waveguide is more than 4.5 mm. For modern printed circuit board applications, this dimension is far too large for practical application. A much thinner parallel plate waveguide is required for integration as a power distribution system in a PCB. In addition, there is often not enough room to locate such a buried structure over the whole area within the PCB. The ability to localize such arrangements would permit chips and other devices attached to the circuit board to have many vias running through the layers of the PCB and would provide much needed isolation and design flexibility.

Accordingly, there is a need for improved circuits, devices and methods for reducing induced power plane noise and improving RF isolation. PCBs and other apparatuses containing such treatments should be thin, permit flexibility in design layout for circuit designers and be cost effective.

### BRIEF SUMMARY

By way of introduction only, the present embodiments provide periodic conductive structures which act as distributed microwave bandstop filters integrated into parallel-plate waveguides. These embodiments can be used as electromagnetic interference (EMI) filters to suppress digital noise on power planes, as well as to eliminate power plane resonances. Hence, they may be used for EMI and EMC (electromagnetic compatibility) purposes in printed circuit boards (PCB). The new structures, when used as part of a printed circuit board design, offer significantly improved RF isolation over what has been attainable in conventional designs using bypass capacitors or buried patches alone.

In particular embodiments, the new structure may be formed as part of a printed circuit board power distribution network to reduce noise coupled from digital switching circuits to power and ground planes of the PCB. An arrangement for power plane noise mitigation (PPNM) using localized unit cells of an array (also referred to as a localized array) rather than providing the unit cells over the entire PCB permits greater latitude in designing PCBs in addition to simplifying the layout and implementation of the PCB. The localized array may be constrained in a particular direction from a central area in which an electrical device is to be mounted such that the localized array terminates in the particular direction substantially before reaching an edge of the PCB and, when the electrical device is mounted on the board, the localized array attenuates electromagnetic radiation of a desired frequency range emanating from the electrical device in the particular direction. The localized array may extend over substantially less than an area of the PCB or layers in the PCB (e.g. signal or dielectric layers) such that only a predetermined number of patches in the array extend in a particular direction from the central area. The number of unit cells of the array in a particular direction may be limited to substantially fewer than a number of unit cells to cover the entire distance between the coplanar locations.

The localized unit cells may be formed using patches and/or chip capacitors (also referred to as surface mount technology or SMT capacitors). The localized patches may be buried below a layer containing signal lines (referred to as a signal layer) or power plane (also to as a Vcc layer), or may be disposed on the same plane as a buried capacitor layer (C-plane layer) or signal layer. The localized chip capacitors are arranged in a lattice of unit cells on one or more surfaces of the PCB and may connect conductive rods extending through the PCB to metal on an opposing metal surface. The conductive rods are otherwise isolated from the metal on the surface on which the chip capacitors are located.

By tailoring the characteristics of the patches and/or chip capacitors, including limiting the area over which these elements are disposed as well as the number of layers within the structure, structures using localized elements may be optimized to produce a stopband in which TEM mode propagation is suppressed over desired frequency ranges. The stopband is the range or band of frequencies over which noise and electromagnetic coupling are suppressed or attenuated. These noise suppression structures of this invention can be made thinner than known noise suppression structures by more than one order of magnitude for the same or better electrical performance.

Some embodiments of the present invention are arranged as periodic structures. As such, the structures have electromagnetic stopbands of frequencies over which TEM modes do not propagate and passbands for TEM modes that propagate in parallel-plate waveguides. Therefore, the structure shares characteristics of electromagnetic bandgap (EBG) filter concepts.

The foregoing summary has been provided only by way of introduction. Nothing in this section should be taken as a limitation on the following claims, which define the scope of the invention.

### BRIEF DESCRIPTION OF THE DRAWINGS

FIG. 1 is a cross-sectional view of one unit cell within a parallel plate waveguide that contains a via, a buried patch, and an SMT capacitor;

FIG. 2 is an isometric view of a chip mounted on a top PCB layer showing buried patches embedded within the parallel plate power distribution network.

FIG. 3 is a top view (via lattice shown) and cutaway view (buried patch treatments shown) of several embodiments of localized buried patch arrays within a parallel plate waveguide.

FIG. 4 shows a 3-cell perimeter-localized buried patch array layer.

FIG. 5 is a cross section view of the 3-cell perimeter-localized buried patch array layer of FIG. 4.

FIG. 6 shows a two 2-cell perimeter-localized buried patch array layer surrounding a metal plane.

FIG. 7 is a cross section view of FIG. 6.

FIG. 8 is an isometric view of a chip mounted on a top PCB layer showing lower layer capacitive plane surrounded by buried patches embedded within the parallel plate power distribution network.

FIG. 9 shows a single cell perimeter-localized buried patch array with SMT capacitors surrounding a metal plane.

FIG. 10 is a typical 8-layer stackup of a known server board.

FIG. 11 is a typical 10-layer stackup of a known server board with capacitive plane technology.

FIG. 12 is a cross section view of an embodiment of an 8-layer stackup with buried patches sharing the signal layers.

FIG. 13 is a top view of an example of a signal layer S2 in FIG. 12.

FIG. 14 is a cross section view of an embodiment of a 10-layer stackup with buried patches.

FIG. 15 is a cross section view of an embodiment of a 12-layer stackup with buried patches.

FIG. 16 is a top view of a parallel plate waveguide test board with three probes, two of which are surrounded by a 5×5 buried patch array with locations for SMT capacitors (none mounted).

FIG. 17 is a bottom view of FIG. 16 showing the SMA connectors for coupling measurements.

FIG. 18 shows a comparison of coupling results for a baseline parallel plate waveguide board, all ports of the hardware in FIG. 16 including localized patch arrays, and buried patches over the entire second metal layer.

FIG. 19 shows a comparison of coupling data for the 5×5 buried patch array in FIG. 21 to a 7×7 buried patch array.

FIG. 20 shows a comparison of coupling results for a baseline parallel plate waveguide board, the 5×5 array of buried patches with SMT capacitors, and the buried patches and SMT capacitors over the entire board.

FIG. 21 shows a parallel plate waveguide with locations for SMT capacitors of which only a 7×7 array of capacitors is located around port 2.

FIG. 22 shows a comparison of coupling results for a baseline parallel plate waveguide board with various array sizes of SMT capacitors surrounding port 2.

### DETAILED DESCRIPTION OF THE PRESENTLY PREFERRED EMBODIMENTS

Applications, such as those in U.S. patent application Ser. No. 10/______ (hereinafter referred to as [1]) filed Mar. 3, 2004, entitled “Circuit and Method For Suppression of Electromagnetic Coupling and Switching Noise in Multilayer Printed Circuit Boards,” which claims priority to Provisional U.S. Patent Application Ser. No. 60/477,152 filed Jun. 9, 2003, entitled “Circuit and Method For Suppression of Transverse Electromagnetic Modes” and concurrently filed U.S. patent application Ser. No. 10/______ (hereinafter referred to as [2]) entitled “Circuit and Method for Enhanced Low Frequency Switching Noise Suppression in Multilayer Printed Circuit Boards Using a Chip Capacitor Lattice,” all of which are hereby incorporated herein in their entirety by this reference, have focused on lattices of patches and/or SMT capacitors. The various arrangements in these applications (containing differing patch and via characteristics) may be incorporated as desired into the arrangements shown in the present application.

Switching of electronic devices such as microprocessors present on a PCB introduces noise in the power distribution network. In addition, the die itself generates impulses, in fact, generally to a much larger extent than the electronic devices (such as drivers). The noise introduced has a fundamental (i.e. lowest) frequency and harmonics related to the switching frequencies of the electronic devices, the materials and geometries used in the design of the PCB structure and other factors. Preferably, the features of the TEM mode suppression circuit disclosed herein are chosen to suppress or limit this noise and thus form an electromagnetic bandgap structure (EBG). The fundamental stopband of the TEM mode suppression circuit may be designed to suppress propagation of the TEM modes at frequencies of interest, e.g. the switching frequencies of the electronic devices. In this manner, noise introduced at a noise source in the power distribution network on either the positive voltage node or the ground node is significantly attenuated at other digital devices or other components of the PCB.

The embodiments described herein attenuate parallel-plate TEM modes that are naturally guided between the parallel conductive surfaces shown in the figures. TEM modes are guided waves moving transverse or across the inside surface of the PPW, in parallel with the plane of the PPW. As shown in the figures, the metal or other conductive planes lie parallel to the x-y plane. A TEM mode has a normal (z-directed) electric field and a transverse (y-directed) magnetic field, assuming wave propagation in the x direction. An empty parallel-plate waveguide (PPW) allows the TEM mode to propagate from DC to an infinite frequency. In this context, an empty PPW is one with no EBG structure. There exists no inherent cutoff frequency for TEM modes in an empty PPW.

The present embodiments create one or more stopbands of frequencies over which TEM modes do not propagate within a PPW. Hence these embodiments may be referred to as TEM mode suppression circuits. Frequency ranges in which the attenuation is substantially less than (10 dB or so) that in the stopband are generally deemed passbands.

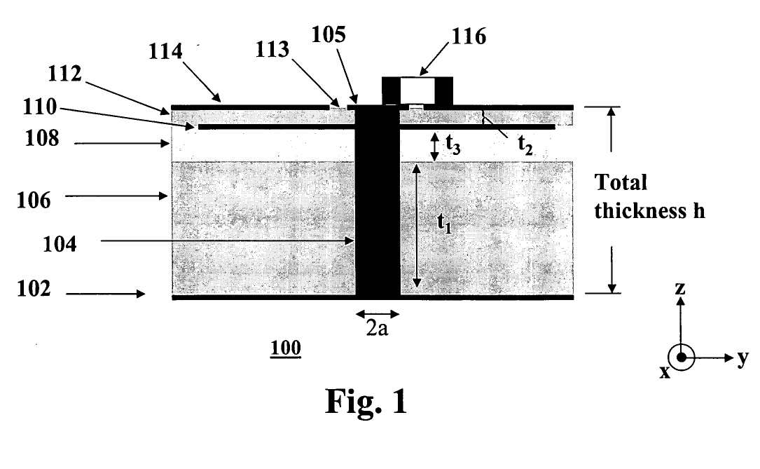

Referring now to the drawings, FIG. 1 illustrates a first embodiment of a parallel plate waveguide (PPW) 100 containing a transverse electromagnetic (TEM) mode suppression circuit. FIG. 1 is a cross-sectional view of the PPW 100. The PPW 100 includes a lower metal layer 102, an upper metal layer 114 separated by three dielectric regions. An array of conductive rods 104 of length h and radius a extends through all three dielectric layers from lower metal layer 102 to the upper metal layer 114. A bonding film 108 of thickness t₃ is disposed between the first dielectric layer 106 of thickness t₁ and the second dielectric layer 112 of thickness t₂. Buried patches are contained in a third metal layer 110 between the second dielectric layer 112 and the third dielectric layer 108 which is the bonding film and make contact with the vias 104. Unless otherwise noted, the dimensions shown in the figures do not include the thickness of the conductive surfaces, which may be a relatively thin metal. The conductive rods may be solid metal poles or may be plated through holes (vias) whose edges are coated with metal but whose centers remain empty. In the latter case, the plated through holes may be buried in a relief formed on the particular layer.

The diameter of the conductive rod is, for example, 40 mils and the overall thickness of the PPW 100 is about 30 mils (thus, FIG. 1 is not illustrated to scale). The conductive rods may, but are not required to, penetrate the entire height of the PCB structure. The thicknesses of the first dielectric layer 106, second dielectric layer 112, and bonding film 108 are, for example, 20 mils, 3 mils and 4 mils, respectively. The length of the conductive rods 104 is about 28 mils, while the total thickness h of the PPW 100 is about 30 mils. The first dielectric layer 106 may be formed of RO5880, the bonding film 108 may be formed of 2 layers of 1080 prepreg, and the second dielectric layer 112 may be formed of FR4 for example. In general, prepreg layers are an epoxy based material containing woven glass fibers for adhering printed circuit board materials together.

The conductive upper layer 114 is not contiguous over the entire surface of the PCB 100. Sections of the upper layer 114 which house ends of the conductive rods 104 are isolated from the rest of the upper layer 114. More specifically, at the periphery of each conductive rod 104, a pad 105 is formed to terminate the conductive rod 104 on the upper surface of the PCB 100. To avoid a short circuit, a clearance space 113 is provided around the pad 105 by etching or some similar means. The clearance space and the diameter of the pad 105 in the embodiment shown in FIG. 1, for example, are preferably kept to a minimum to maximize the capacitance between the patches 110 and the conductive surface of the upper layer 114.

The conductive rods 104 are oriented generally normal to both the lower layer 102 and the upper layer 114. Each respective conductive rod 104 is in electrical contact with the lower layer 102 and the buried patch 110. In some embodiments, each conductive rod 104 has an associated capacitor 116 and/or patch 110. The capacitors 116 (in one embodiment chip or SMT capacitors such as 1800 pF, 50 VDC capacitors made by Panasonic, Digi-Key P/N PCC2157CT) connect the pads 105 with the conductive upper layer 114. The capacitors 116 add a fairly large capacitance to the structure, compared to structures containing only patches 110.

The conductive rods 104 and capacitors 116 in the embodiment of FIG. 1 are arrayed in a square lattice of period d (for example, 250 mils). Various structures and reasons for using lattices are provided in U.S. Pat. Nos. 6,512,494 and 6,262,495 herein incorporated by reference in their entirety. The first and second dielectric layers 106, 112 form the host dielectric medium of the PPW 100. The first (lower) dielectric layer 106 of thickness t₁, contains the conductive rods 104, has a relative dielectric constant of εᵣ₁, while the second (upper) dielectric layer 112 has a relative dielectric constant of εᵣ₂. One example of materials used for the lower dielectric layer includes RO5880, which has a dielectric constant of 2.5, and used for the upper dielectric layer includes FR4, which has a dielectric constant of 3.9. As will be described in greater detail below, in an embodiment containing patches, t₂<t₁, and εᵣ₂≧εᵣ₁.

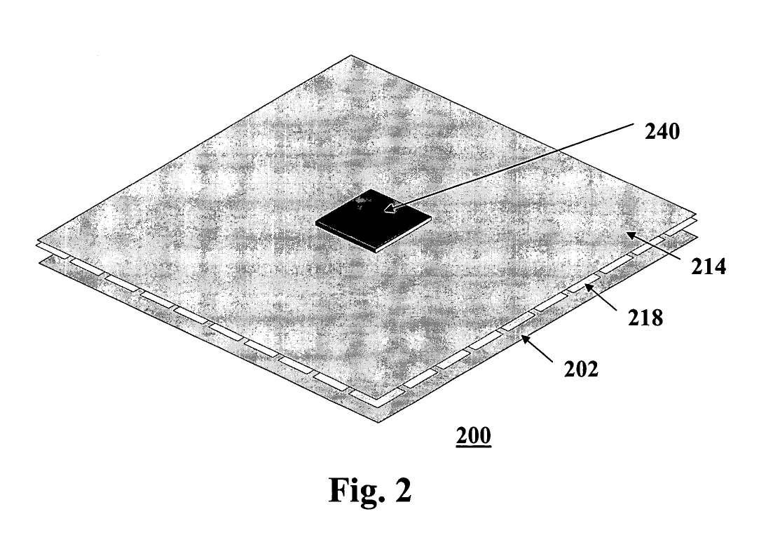

FIG. 2 illustrates a perspective view of a multilayer PCB (only three layers are shown for clarity) where a chip 240 is located at the center. The PCB 200 contains a ground plane 202, patches 218 connected through conductive rods (not shown) to the ground plane 202 and a power plane 214. An electronic device 240 is disposed above the power plane 214 and may be connected to the ground plane 202 and power plane 214 through conductive connections (not shown). The PCB shown 200 may be a section or portion of a larger PCB in which there may or may not be a buried patch layer. In the region 200 there may be many different local arrangements of the buried patches such as square or rectangular shapes, perimeter boundaries, and other uniform or non-uniformly sized structures. The electronic device is a surface mount device that may be wave soldered or reflow soldered to metallized pads on the surface of the PCB. In other embodiments, the electronic devices may include legs or posts that extend through conductive rods in the PCB. Signal traces and the conductive rods route signal nodes and power and ground within the PCB. The signal traces lie on the surface or in planes generally parallel to the surface of the PCB. The conductive rods, in contrast, extend vertically, normal to the surface.

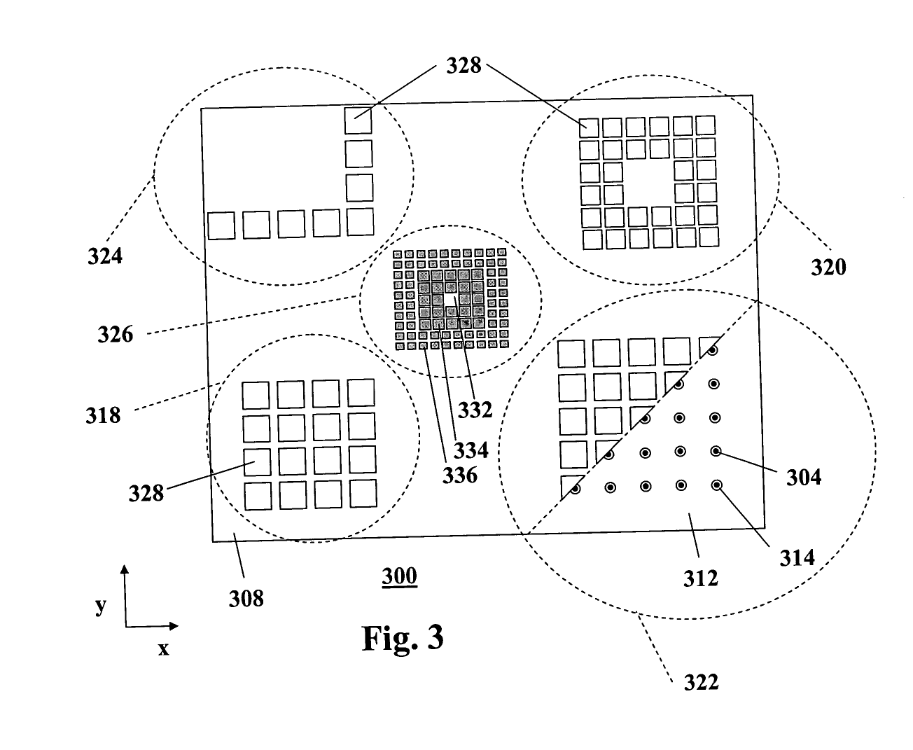

FIG. 3 illustrates a cutaway view of a PCB with several embodiments of localized patch arrays: a 4×4 buried patch array 318, a 2-cell wide perimeter boundary 320, a 5×5 buried patch array 322, an L-shaped open boundary 324, and a localized perimeter boundary with two patch sizes 326. A first dielectric material 308 exists below the layer of localized patches 328 and above the ground plane (not shown). All patches illustrated in FIG. 3 reside on the same PCB metal layer. A second dielectric material (not shown) is disposed above the metal layer containing the patches. Above this second dielectric material is another metal layer 312 that forms the Vcc plane. This Vcc plane is not contiguous as it contains isolated via pads 304 which are not connected to Vcc. In any of these configurations, SMT capacitors may be connected on one end to the via pads 304 and the other end to the VCC plane 312. Conductive rods 304 connect the ground plane layer to the buried patches and to the isolated via pads as illustrated in the cut-away view 322.

As noted above, in many board designs, it may not be practical to have a continuous lattice of patches and capacitors below or adjacent to the chip. In general, the chips have many pin connections to their package that lead to a high density of interconnections to the signal layers and other layers of the board. In FIG. 3, a number of localized buried patch arrays are shown with an open region in the center (320, 324, 326). The open regions are devoid of patches in order to accommodate the complex interconnection densities of chips. SMT capacitors may also be placed in a localized array surrounding electronic devices that are the source of, or are susceptible to, EMI. When the SMT capacitors are used in conjunction with buried patches in localized arrays, there are distinct low frequency and high frequency stopbands as will be discussed below.

In some cases, the patches may not exist below the chip on all sides of the chip. In embodiment 324 of FIG. 3, patches are not included in the corner near the edge of the board. Thus, as shown, TEM modes traveling toward the edge of the circuit board are not attenuated in this direction. This permits fewer patches to be used while still protecting circuitry from TEM modes traveling toward the center of the board. For some applications, it may be advantageous to prevent the TEM modes on the power planes generated by a chip located near the corner of the board from reaching the edge of the board. This situation is addressed in the embodiment 320 in which the rings of patches surround the area where an electronic device is connected to the power and ground planes. This embodiment is particularly useful for preventing EMI from being propagated omnidirectionally through all the planes by a radiating high speed chip on the board. As in any of the embodiments, any geometry and placement of the array may be used so long as the TEM modes are attenuated in one or more desired directions. In one example, a simple “wall” of several unit cells of patches and/or chip capacitors between two positions separated by the wall may be used to reduce power plane coupling between chips and to reduce power plane coupling between chips.

Although embodiments 324 and 320 of FIG. 3 illustrate rings of one or two periods of patches, this is merely exemplary. Any number of periods of patches and/or capacitors may be used to protect the electronic device from noise within the parallel plates of the power distribution network in the desired frequency range. The structures also serve to protect other circuitry near the electronic device from noise generated by the electronic device.

Patches can completely surround an open central region and change in size with distance from the central region. Inhomogeneous mode suppression structures may be created to allow broader frequency stopbands between two different reference plane locations on the same PCB. In these structures, the stopband edges vary in frequency as a function of lateral position within the PCB because the properties of the unit cell change with location. One example of such a structure is shown in embodiment 326 of FIG. 3. In this embodiment, the patches decrease in size from the central region 332. The array of patches contains larger patches 334, and smaller patches 336. As mentioned, these different patch and unit cell sizes attenuate the electromagnetic waves within different frequency regions. Although only 2 unit cells of each type of patch are shown, more unit cells or fewer unit cells may be present. In addition, although the patch size shown in FIG. 3 decreases with increasing distance from the central area, the patch size may increase with increasing distance or alternate such that the size increases then decreases or decreases then increases.

Although the previous figures show that the patches surrounding the electronic device are of similar shape, the patches may not be required to have the same characteristics (e.g. size, shape, orientation among others) in orthogonal directions. Similarly, the characteristics of the chip capacitors (e.g. capacitance value) may vary depending on the direction from the central area. Of course, as in any of the embodiments, shapes other than square or rectangular (e.g. hexagonal, triangular, circular, ovate) may be used to create the patches so long as waves of electromagnetic energy at the desired frequencies are attenuated between the points of interest.

One observation made in [2] is that a simple parallel plate waveguide consisting of a dielectric and two metal surfaces (e.g. C-plane) can always be made thinner than a noise suppression circuit containing buried patches. For instance, in FIG. 1, the noise suppression circuit is of total thickness t₁+t₂+t₃, whereas a C-plane structure could be made as thin as t₂. This issue does not have a negative impact on the total board thickness since the parallel plate waveguide with noise suppression circuits of the present invention can still be made as thin as 4-8 mils for some applications. However, there are some instances in which it is necessary to have the power and ground planes separated by a very thin dielectric layer directly beneath the chip so that enough charge will be available to the chip when the transistors switch at high frequencies. If sufficient charge is not available at all the frequencies in which the charge is demanded, then voltage fluctuations will be induced on the power planes. However, the use of a thin parallel plate waveguide for DC power distribution is not the complete solution to noise and interference problems as this structure does not suppress TEM modes. Embodiments of the present invention address a method for providing a thin power distribution network beneath the chip as well as localized patches for suppression of noise and interference signals. This solution provides stopbands for attenuating noise between various chips without decreasing the charge available to the chip at the higher frequency bands.

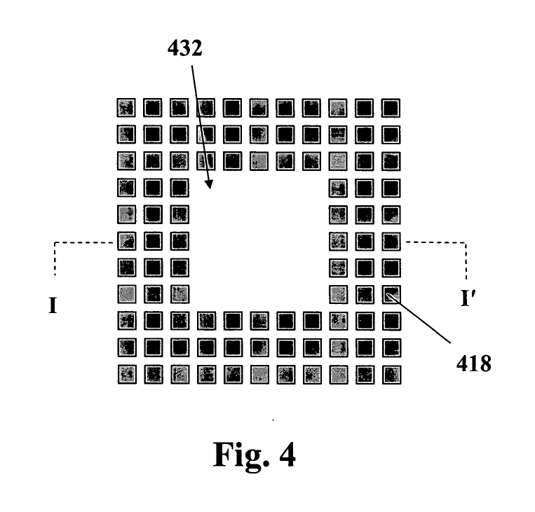

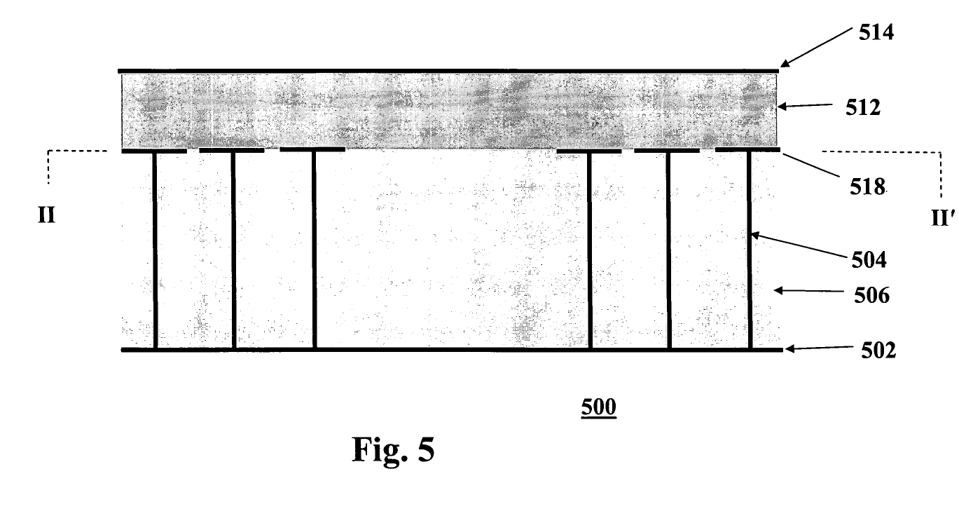

FIG. 4 shows a localized ring of patches 418 around a central region devoid of patches 432. FIG. 5 is a cross-sectional view of the embodiment of FIG. 4 that does not show any chip capacitors disposed on the PCB 500. As with the other embodiments, however, chip capacitors may be present elsewhere on the PCB 500 in the same or a different array as the patches 518. The cross-sectional view of FIG. 5 is shown as the sectional taken across line I-I′ in FIG. 4. The top view of FIG. 4 is shown as the sectional taken across line II-II′ in FIG. 5. The patches 518 are connected through conductive rods 504 to a lower plane 502. The patches 518 are more proximate to the upper plane 514 than to the lower plane 502. The upper and lower planes 514 and 502 have different potentials and may be, for example the power and ground planes. The total thickness of the structure may be 2, 3, 4, 6, 8, or 10 mils, which is sufficient for most commercial uses.

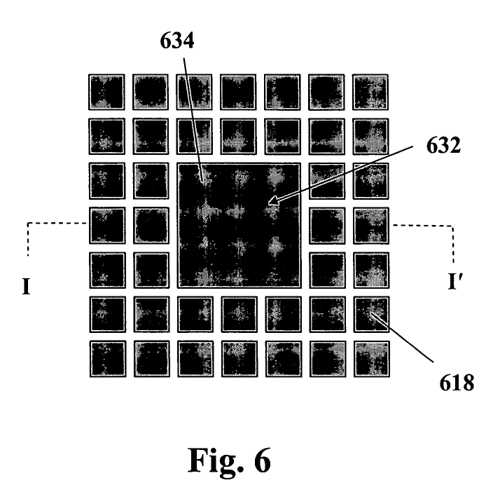

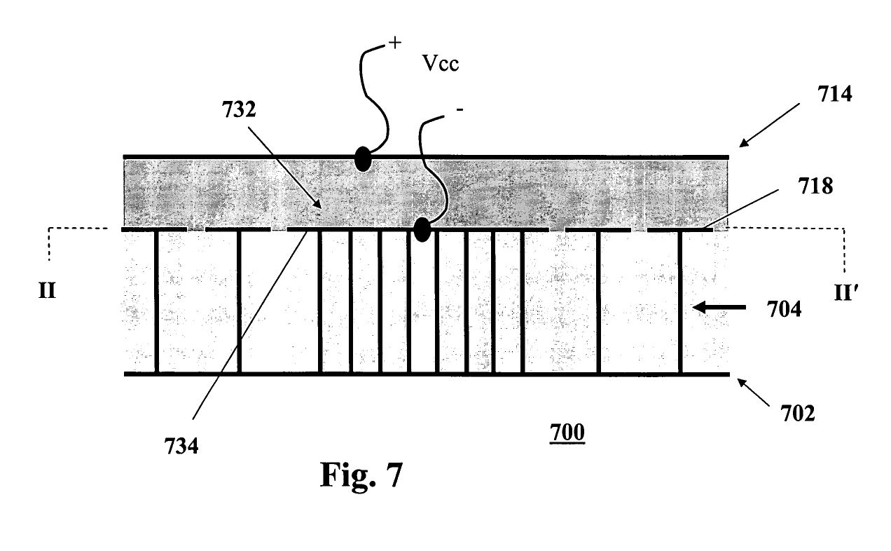

FIG. 6 is a top view of an embodiment similar to that shown in FIG. 4, but in this embodiment, the central area 632 contains a metal plane 634. Again, only the patches 618 are shown as completely surrounding the plane 634, although chip capacitors can be also mounted on a different layer. FIG. 7 is a cross-sectional view of the embodiment of FIG. 6 that does not show any chip capacitors disposed on the PCB 700. As with the other embodiments, chip capacitors may be present elsewhere on the PCB 700 in the same or a different array as the patches 718. The cross-sectional view of FIG. 7 is shown as the sectional taken across line I-I′ in FIG. 6. The top view of FIG. 6 is shown as the sectional taken across line II-II′ in FIG. 7. The metal plane 734 in the central area 732 and patches 718 outside the central area 732 are connected through conductive rods 704 to a lower plane 702. The patches 718 and metal plane 734 are more proximate to the upper plane 714 than to the lower plane 702. The upper and lower planes 714 and 702 have different potentials (Vcc) and may be, for example the power and ground planes. Since the metal plane 734 is connected to the ground plane 702 through many vias, the charge supply for the chip essentially comes from the large capacitor formed by the metal plane 742 and the Vcc plane 714. This embodiment is superior to both the case having buried patches only and the case having a thin parallel plate waveguide occupying the entire lateral dimension of the board such as a ZBC2000 buried capacitance layer, providing both space savings and an enhanced frequency range.

The capacitive plane (C-plane) structure alone can be applied to the entire PCB to provide a high-speed capacitive tank that can sink or source high frequency current near the electronic device (e.g. an integrated circuit or driver) up to about 3 GHz. The C-plane also ideally reduces the effective complex impedance of the power plane structure by decreasing the inductive reactance X_{L}, which suppresses V_{CC} plane resonances, especially those that stimulate resonance modes in the entire PCB structure. The results combine to reduce common mode RF currents in the ground plane up to the C-plane's maximum operating frequency. Ultimately, this not only suppresses TEM waves produced between the power planes, but it also increases the effectiveness of differential PCB components, such as local decoupling capacitors and input/output (I/O) filters.

The use of a C-plane or the use of C-plane islands supplies charge to electronic devices that draw large amounts of complex high, medium and lower frequency current simultaneously. In actuality, the high-speed capacitive tank only operates effectively within a certain radius (the Radius of Effective Capacitance or REC) from the electronic device. It is within this disk where nearly all of the very high-speed charge exchange is occurring. The REC depends upon the velocity of propagation in the PPW and the rise time tᵣ of the signals demanding charge. For example, using a typical FR-4 substrate/dielectric and copper planes, if the rise time tᵣ=1000 ps, the REC disk is approximately 1.2″ (30.5 mm) in radius. This is equal to the actual charge exchange radius from a hypothetical 1 GHz (Bandwidth) device, and the useful diameter of the REC is 2.4″ (61 mm). Similarly, if tᵣ=400 ps or 200 ps (a high speed driver), the REC disk is about 0.50″ (13 mm) or 0.25″ (6.5 mm), respectively. In summary, a C-plane's ability to actually deliver charge at high speeds is decreasing as the speed of electronic devices increases.

The combined C-plane and buried patch array has a low transfer impedance to the electronic device and may be designed to be exactly as large as needed (have the desired REC) for multiple rise time RF spectra produced by the electronic device. In addition, the surrounding buried patch array suppresses noise and coupling above the frequencies in which C-plane fails to deliver charge. As few as 1 unit cell of the buried patch array surrounding the C-plane may be effective in attenuating the waves, thereby leaving plenty of real estate for designs using many interconnections that pass through the board.

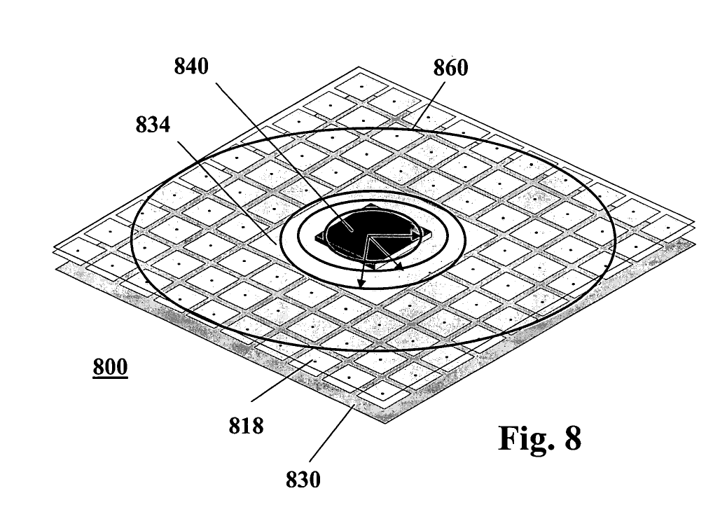

FIG. 8 illustrates the above discussion of C-plane, buried patches, and radius of effective capacitance. The PCB 800 contains a ground plane 830 connected to the array of patches 818 and the C-plane 834 that form the noise suppression circuit. The electronic device 840 (e.g. IC or driver) sits on a layer above the C-plane 834. The concentric circles 860 indicate the REC disk at various frequencies. The REC size decreases with increasing device speed and frequency. When the C-plane layer is combined with an array of buried patches and SMT capacitors mounted on the buried patches a broad stopband is produced with enhanced low frequency suppression which allows sufficient charge to be supplied to high speed electronic devices. Control of the REC and the design of 1, 2, 3, or more rings of patches around a reduced-size C-plane provide a wideband solution to TEM mode wave generation and propagation.

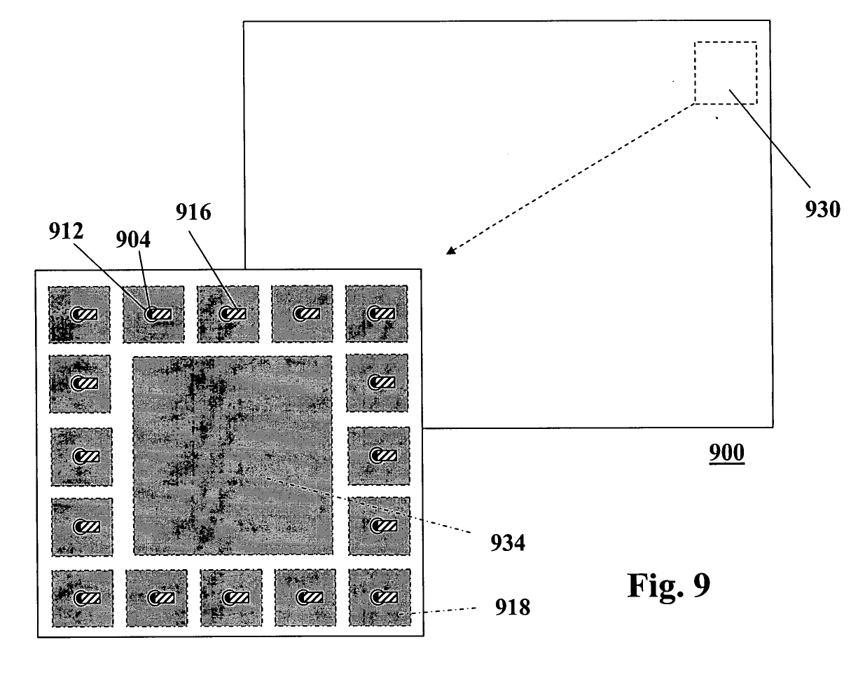

FIG. 9 illustrates a PCB 900 that includes one or more localized areas 930. The localized area 930 shown in the inset includes an array of buried patches 918 and a C-plane 934 on one layer and chip capacitors 916 on another layer. The conductive rods 904 extend through the layer containing the patches 918 and C-plane 934 to the layer containing the chip capacitors 916. The top metal plane on which the capacitors reside is not shown for convenience. The conductive rods 904 are separated from the remainder of the layer on which the chip capacitors 916 are disposed by the dielectric layer 912 or otherwise recessed. The conductive rods 904 also connect the patches 918 with a ground plane (not shown). In fact, although not shown, as in each of the previous embodiments, multiple rods may connect one or more of the patches 918 to the ground plane, as shown in U.S. patent application Ser. No. 10/______, incorporated by reference above, in order to decrease the effective inductance of the vias.

In the embodiments shown in FIGS. 6-9, the C-plane and patches are formed on the same layer, thereby decreasing the overall number of layers. However, in general, the C-plane and the plane containing the patches do not need to be formed on the same plane.

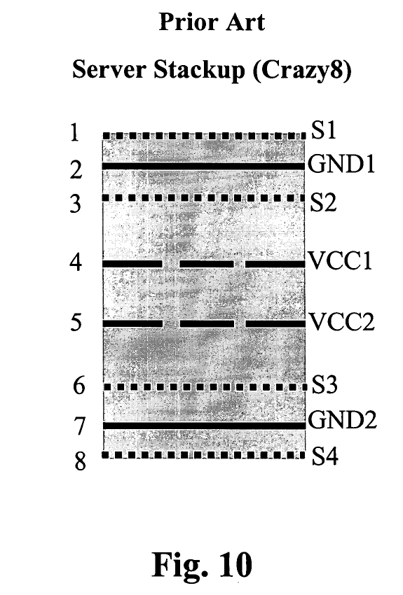

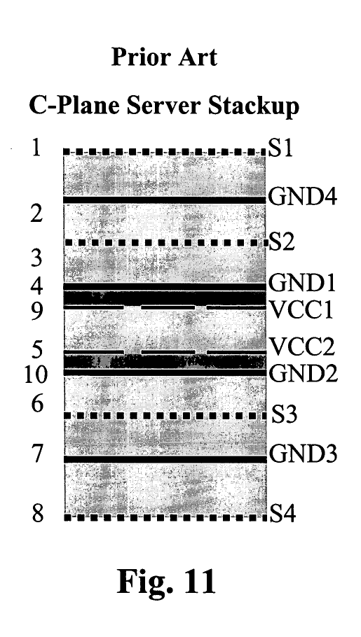

FIGS. 10 and 11 show typical embodiments of known computer board stackups that contain multiple power and ground planes in one PCB. Although server layouts are shown, other stackups such as those used for desktop or portable systems contain embodiments similar to those shown. Layer numbers are shown to the left of the stackup and the description of the particular layer's function is shown to the right of the stackup (FIGS. 10-15). S1, S2, and S3 refer to signal layers. The dielectric layers separating each plane are not labeled and may be composed of different materials such as FR4 and prepreg in the embodiments of the present invention. Various patch and/or chip capacitor arrangements described herein may be used in the structures. Also, although several illustrations of the present invention have shown the localized patches being connected to the ground plane, they may instead be connected to the internal power plane(s) and disposed close to the adjacent ground plane, with the ground plane disposed between the power plane and the signal layer in which the noise is to be attenuated. In addition, although localized arrays of chip capacitors can be used alone or in combination with any of the patch arrangements in each of the structures, arrangements containing chip capacitors will not be further shown or described for convenience sake.

FIG. 10 shows a conventional server board stackup that does not contain any noise mitigation techniques. This conventional server structure (called Crazy 8) contains 4 layers containing signals (S1, S2, S3, and S4), two ground planes (GND1 and GND2), and two power planes (Vcc1 and Vcc2). Each plane is separated by a dielectric layer, for example FR4. The two power planes are adjacent to each other, the ground planes are disposed between the power planes and the top and bottom of the PCB, and the signal lines are disposed at the top and bottom of the PCB and between each ground plane and the power plane pair. The total thickness of this stackup is approximately 93 mils. There are nominally 6-7 mils of dielectric material separating each signal layer from its nearest ground plane. The internal signal layers (S2 and S3) are separated from their nearest Vcc planes by about 16 mils. These distances are made large in order to minimize the coupling of the signal layers to the split Vcc planes. In the crazy-8 configuration of FIG. 10, the Vcc layers are split in order to facilitate multiple voltages within the board stackup. Traces which are routed next to split planes are a major source of EMI. The Vcc planes on layers 4 and 5 of FIG. 10 are separated by 20 mils.

The structure shown in FIG. 10 has several deficiencies. In particular, the supply of high frequency charge is limited since the ground and voltage planes are widely separated (for example, no C-planes), a large amount of crosstalk exists between the VCC1/VCC2 layers thereby creating mode TEM waves, and the signals on S2 and S3 are prone to cut across splits on the VCC1 and VCC2 which generate even more common and differential mode noise. All of these cause very high levels of TEM waves to be generated.

A conventional stackup using C-plane structures is shown in FIG. 11. The C-planes are embodied in this example by GND1 next to VCC1 and GND2 next to VCC2. This results in two additional metal regions and two additional dielectric regions within the board stackup of FIG. 10. The new ground planes, as discussed above, are disposed close to the power planes, between the power planes and the signal layers adjacent to the power planes. One advantage of this structure is that the internal signal layers are no longer routed next to split Vcc planes. Other advantages include the existence of individual high-frequency charge supplies for every IC as well as reduced inter-VCC crosstalk. A Vcc plane and its nearest ground plane in FIG. 11 are separated by 3 mils.

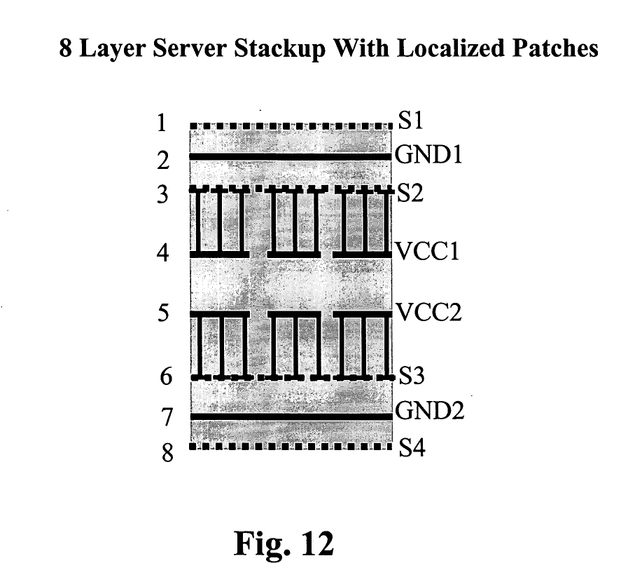

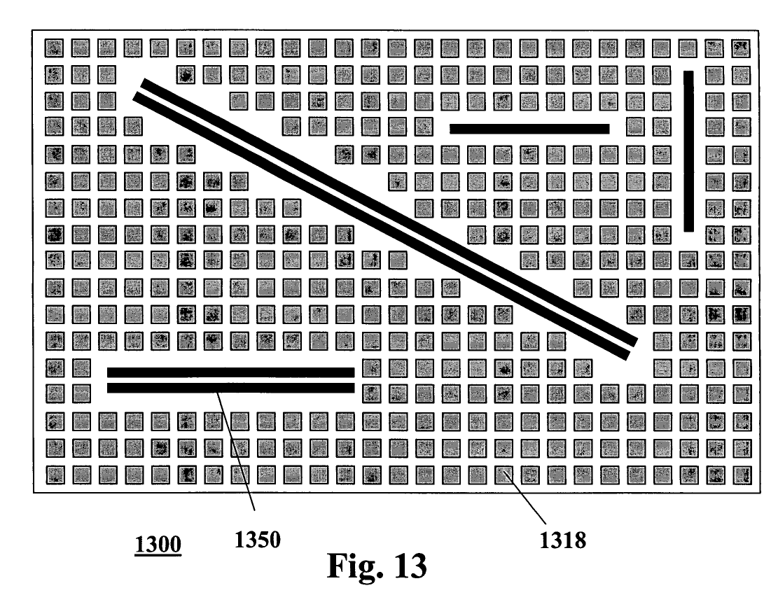

FIG. 12 is one embodiment of the present invention using localized patches that also solves the EMI problem of the stackup in FIG. 10. In this embodiment, the arrays of patches are placed on signal layers S2 and S3. These localized arrays of patches are connected to the Vcc planes with vias. Alternatively, the patches could be connected to the ground plane with vias; however, the embodiment of FIG. 12 maximizes the capacitance of the buried patches. As discussed in [1] and [2], greater capacitance leads to greater stopband bandwidth. An example illustration of layer S2 or S3 in FIG. 12 is shown in the layer 1300 of FIG. 13. In this example, patches 1318 are disposed over all sections of this layer not occupied by signal traces 1350. One advantage of this embodiment is that it provides noise suppression that is better than using C-planes alone and without the need to add additional layers to the board. In other embodiments, localized patches may be used having the localized patch arrangements described previously.

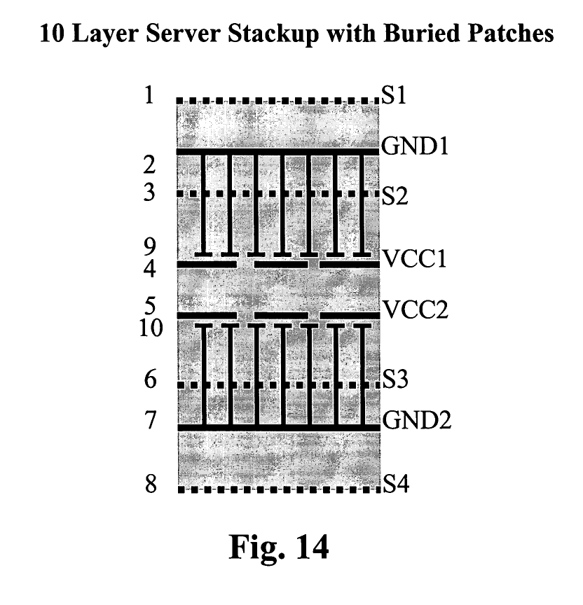

However, greater EMI suppression may still be obtained using embodiments with extra layers. FIG. 14 is an embodiment using localized patches that are very close to the power planes VCC1 and VCC2. In one embodiment of the structure of FIG. 14, a prepreg layer that is 2 mils thick is used between layers 4 and 9 and between layers 5 and 10. As shown in FIG. 14, the localized patches are connected to the ground planes through conductive rods that extend through the dielectric layers between the various planes. The conductive rods extend through the signal layer between the ground plane and power plane. Arrays of patches may also be formed on the signal layers in addition to forming patches close to the power planes. An advantage of this embodiment over that of FIG. 12 is that the patches can be placed much closer to one of the planes (Vcc or ground) such that the capacitance and, in turn, the stopband bandwidth are maximized. In other embodiments in which multiple signal layers are present between the power and ground planes (such as stackups for portable computer PCBs), the conductive rods extend through the signal layers with or without patches being formed on the signal layers. In general, as in all of the other PCB stackups, the layer of patches can be disposed next to the ground plane or the Vcc plane in a given circuit. Either configuration will server to attenuate noise and interference within the parallel plate waveguide in which the circuit is place.

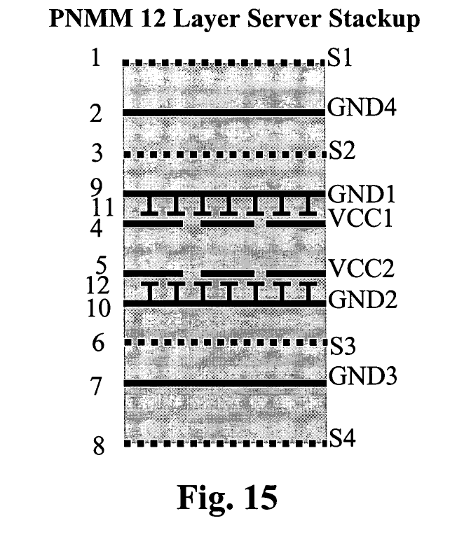

FIG. 15 shows a cross-section of a PCB having 4 additional layers added to the original 8-layer structure of FIG. 10. Such a structure improves suppression to frequency ranges such as 3-10 GHz, which is far beyond the operating range of C-plane technology and also beyond the operating range of isolated SMT decoupling capacitors. The arrays of buried patches in this case may be localized or they may cover the entire surface of the plane that they occupy. As can be seen in this figure, there are 12 symmetrically disposed layers: signal layers on opposing surfaces of the PCB, signal layers internal to the PCB, ground planes disposed between the internal signal layers, power planes adjacent to each other disposed in the center of the PCB, C-planes disposed between the power planes and the internal signal layers, and layers containing global or localized arrays of patches disposed between the C-planes and the power planes. The patches may be connected to either the ground plane or VCC plane of the C-plane through conductive rods.

In FIGS. 12, 13, and 15, the conductive rods are shown as buried vias. It is not necessary that the vias be buried. The vias could also be plated through holes that penetrate all layers of the PCB but are only connected to layers that they are shown to contact in the figures. For example, in FIG. 15 the vias disposed between GND1 and VCC1 are only connected to GND1 and the patches on layer 11 but are isolated from any metal traces and conductors on all the other layers.

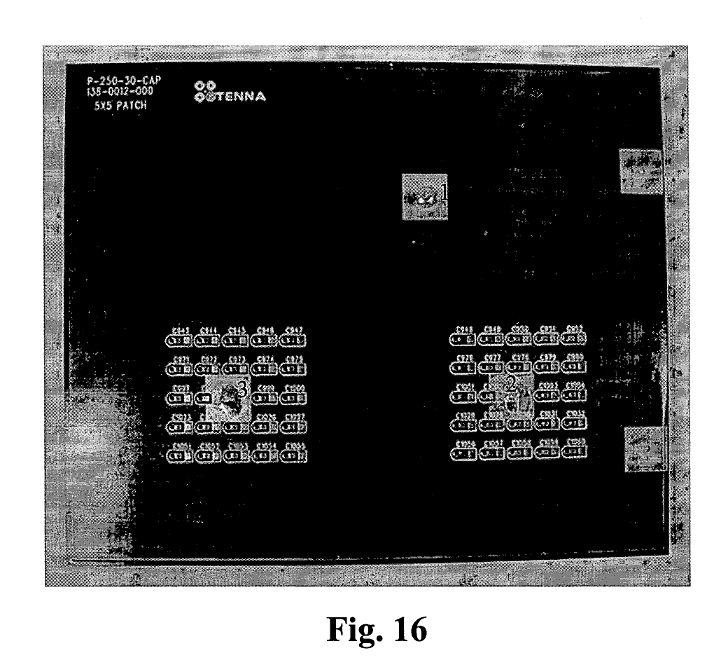

Now we turn to experimental results of localized arrays of patches and capacitors. Experiments were performed to test the actual frequency response of different types of arrangements: those in which the arrays of patches and/or chip capacitors extend throughout the PCB and those with localized arrays. A top view of a parallel plate waveguide with 5×5 arrays of buried patches around ports 2 and 3 is shown in FIG. 16. Pads are available for SMT capacitors to be mounted. However, there are no SMT capacitors mounted on the board in this figure. The PCB is of dimensions 4.25 inches by 5.25 inches. The patches are squares having 230 mils side dimension and a spacing of 20 mils between the patches. The stackup of this board is the same as that shown in FIG. 1. The dielectric layer between the patches and the bottom layer is 24 mils thick and has a relative dielectric constant of 2.5, the dielectric layer between the patches and the top layer is 3 mils thick and has a relative dielectric constant of 3.8. Thus, the period of the localized array of patches is 250 mils and the parallel-plate capacitance between a single patch in a unit cell and the Vcc plane is about 14.7 pF. Each conductive rod, which extends from the bottom layer to the top layer, has a radius of 20 mils. The 5×5 localized array is very similar to embodiment 322 in FIG. 3 except that the middle patch is completely eliminated.

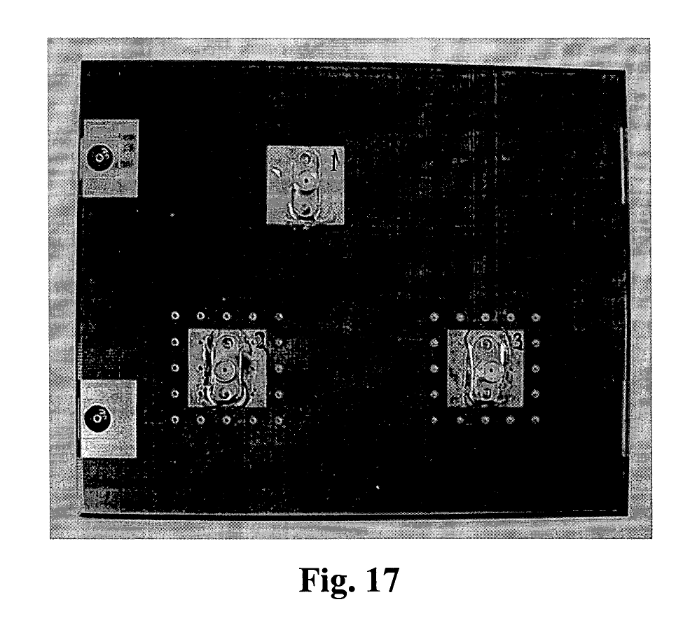

Three SMA connectors were soldered to bottom side of the PCB and were centered on drilled-out vias as illustrated in FIG. 17. The center conductor for each connector was soldered to the top conductive surface of the PPW and the outer conductor was soldered to the bottom surface so as to excite and receive TEM-like modes. As can be seen in FIG. 16, only the SMA connectors (i.e. no chip capacitors) were installed on the base PCB by soldering. Ports 1 and 2 were separated by 1.9 inches, ports 1 and 3 were separated by 2.5 inches, and ports 2 and 3 were separated by 2.5 inches. Again, the materials and geometries are exemplary only.

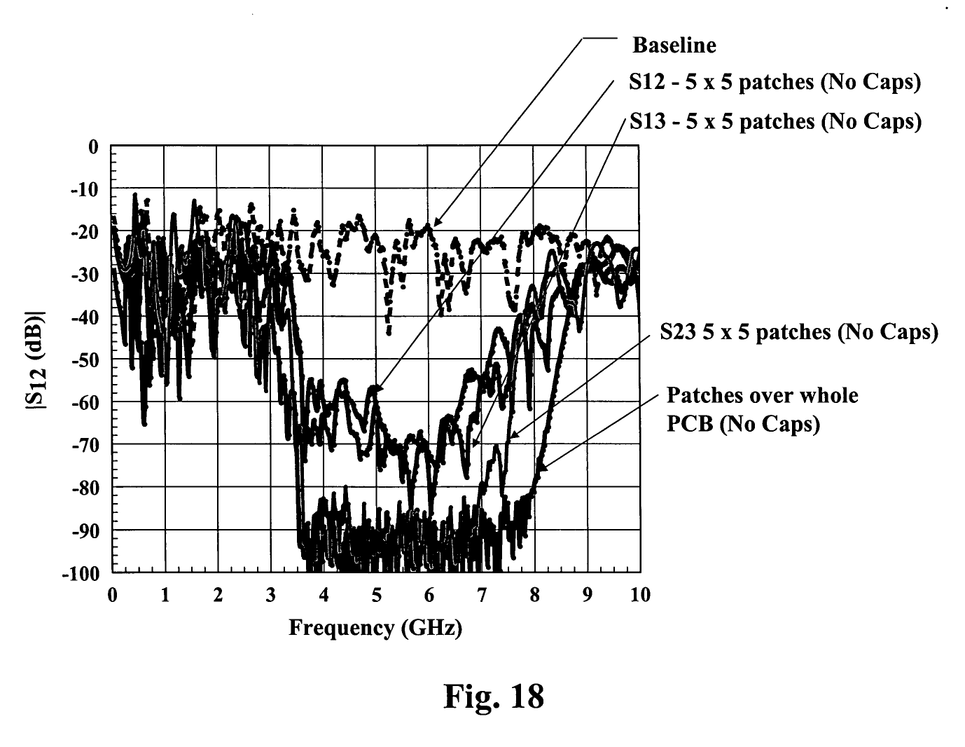

The coupling data between all three ports of the hardware shown in FIGS. 16 and 17 is graphed in FIG. 18 as S12, S13, and S23. For comparison are data from two other boards: a baseline PPW without noise suppression and a board with buried patches covering an entire layer. Both these other two boards have the same dimensions and stackup as the board of FIGS. 16 and 17. Ports 2 and 3 are in the middle of and are completely surrounded by a 5×5 array of buried patches. These 5×5 arrays can also be described as two rings of square unit cells. Port 1 does not have any patches surrounding it. The coupling data S12 in FIG. 18 indicates that there is significant isolation between port 1 and port 2 (S12) with only 2 rings of unit cells surrounding port 2. The same statement can be made regarding port 3 (S13). The isolation data of S12 and S13 are about the same. Thus, the frequency response does not vary dramatically with a variation of distance between the ports if the same number of unit cells exists between the ports. As expected, the attenuation in the stopband increases with a corresponding increase in the number of unit cells between the ports. Since there are four cells between ports 2 and 3, the attenuation is much greater for S23 than for S12 and S13. As shown in FIG. 18, the average attenuation in the stopband is around −70 dB for 2 unit cells between ports (S12, S13) and is around −90 dB for 4 unit cells between the ports (S23). All cases show significant improvement over the baseline case over the band 3.5-7.5 GHz.

It is evident from FIG. 18 that, when both measured ports (2 and 3) are centered amidst the 5×5 squares of buried patches, the resulting S23 frequency response is similar to that of an arrangement in which the patches are present over the entire PCB. Thus, only a few localized unit cells in the region nearest a given electronic device are very effective for reducing mutual coupling and a complete treatment of the layer is unnecessary.

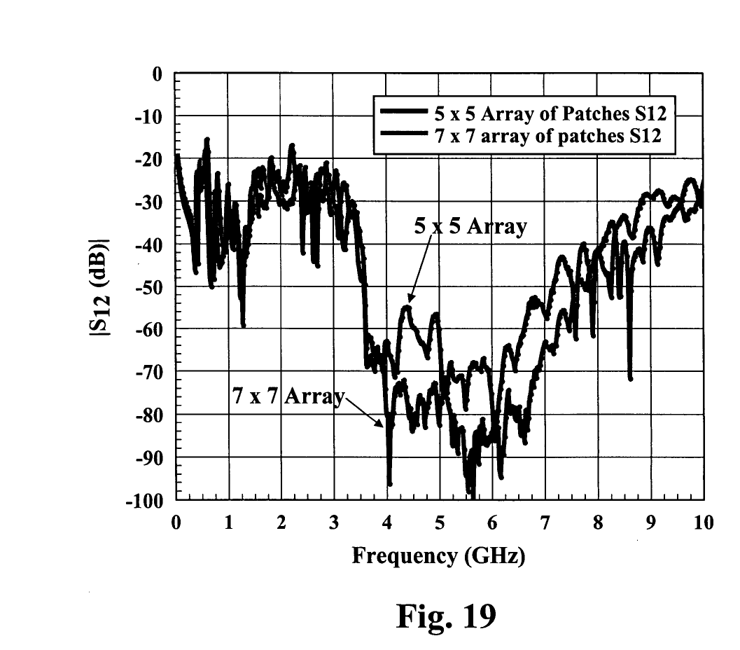

FIG. 19 is a comparison of the coupling data for a 7×7 array of buried patches and a 5×5 array of buried patches. In both cases, the second port is not surrounded by any patches. The 7×7 array of patches can be thought of as three rings of unit cells completely enclosing the SMA connector port. As expected, the level of attenuation increases and the stopband bandwidth increases as the number of unit cells between the ports is increased.

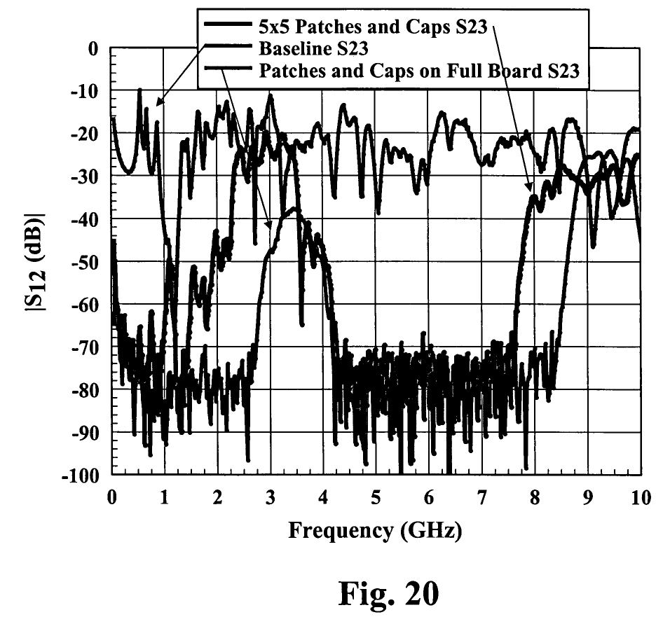

FIG. 20 illustrates a comparison between arrangements in which no patches or capacitors are present (baseline), 5×5 arrays of capacitors and patches are disposed around both ports, and the entire board is filled with an array of capacitors and patches. In both cases, it is evident that the various bands become more defined with increasing number of unit cells between the ports. The upper edges of the stopbands shift to higher frequency by about 1 GHz and the attenuation in the passband between the two stopbands increases when the unit cells fill the whole board. However, there is still significant isolation improvement at both a high frequency band (4-8 GHz) and a low frequency band (less than 2 GHz) compared to the baseline when localized buried patches and capacitors surround both ports.

Note that although a passband is shown between about 2.5-3.5 GHz in FIG. 20, this passband may be decreased or eliminated by different combinations of changing the capacitance of the chip capacitors, changing the capacitance formed by the patches (through changing the size of the patches or the dielectric constant between the patches and the conductive surface for example), or changing the different inductances (through changing the size, number, and/or distribution of the vias for example).

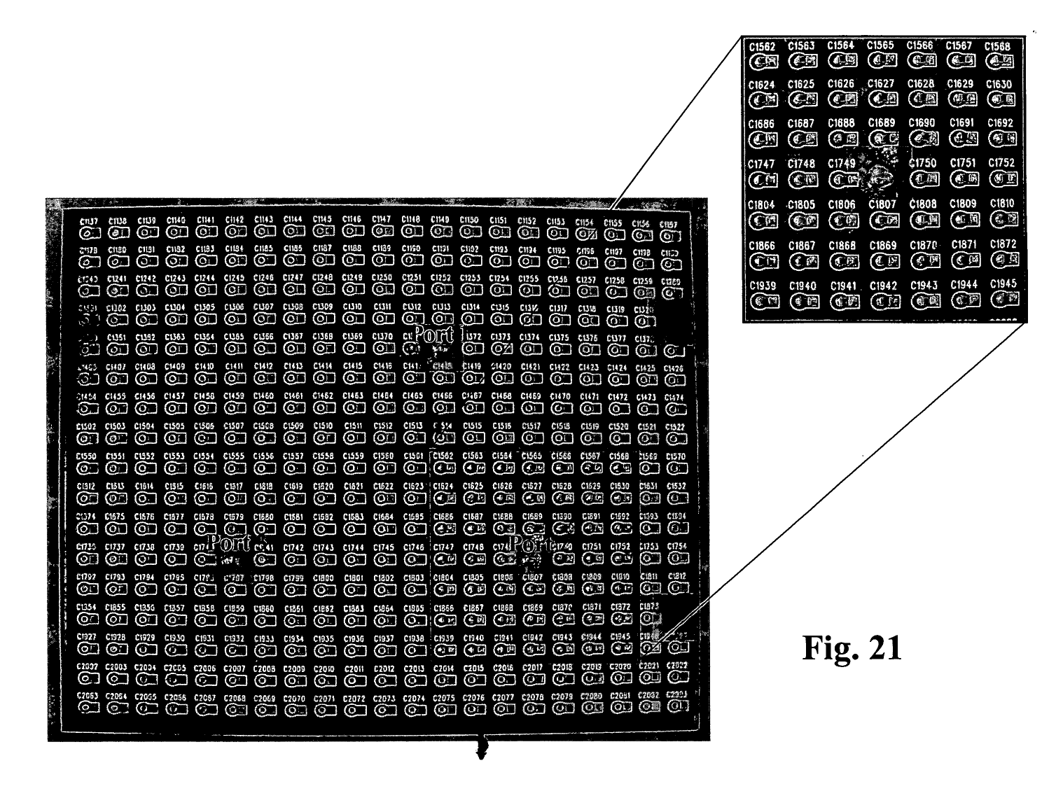

FIG. 21 shows a PCB having vias and pads available for mounting SMT chip capacitors with a 250 mil period on the top surface of the whole board. The port locations, stackup, and dimensions are the same as the hardware illustrated in FIGS. 16-17 except that there are no buried patches. The inset shows port 2 surrounded by a 7×7 array of 1800 pF SMT chip capacitors. This case corresponds to a total of 48 capacitors since there is no capacitor located in the center where the port exists. However, there is no reason why a capacitor could not have been located at this position too. The 7×7 lattice of capacitors represents three rings of unit cells completely encircling the port. There were several additional cases that where fabricated and measured leading up to the 7×7 array that are not shown. One ring of unit cells around the port formed a 3×3 array of 8 capacitors, and two rings of unit cells formed a 5×5 array of 24 capacitors. A 6×6 array of 34 capacitors was also tested. In this case the port was not in the exact middle of the lattice.

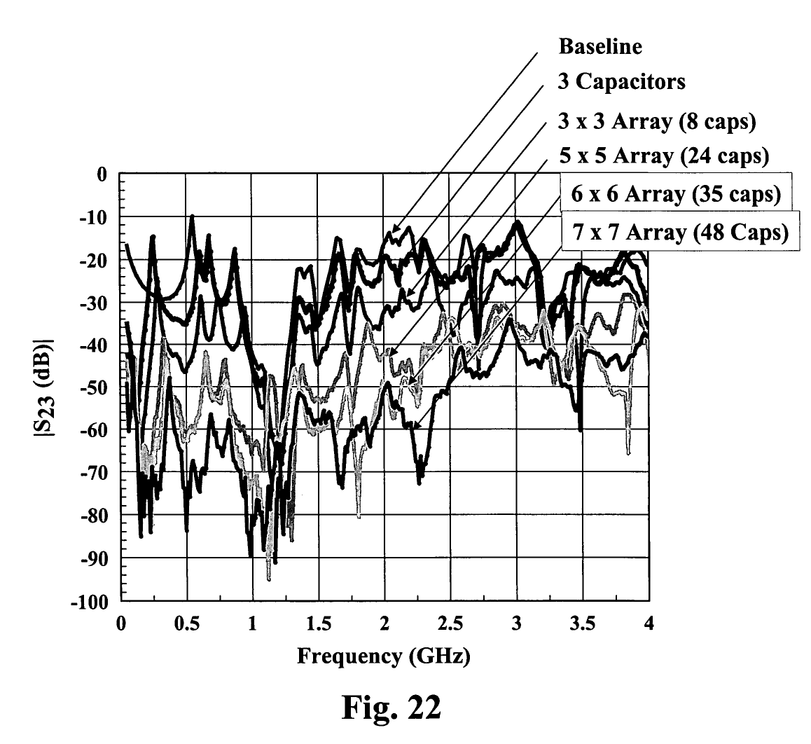

The coupling data for the various arrays of SMT capacitors mentioned above are graphed together in FIG. 22 along with data for a baseline PPW without capacitors and the case having 3 capacitors near port 2. The frequency response when only 3 chip capacitors are used is effectively the same as the baseline frequency response for frequencies above 250 MHz. As shown in FIG. 22, adding one unit cell (8 capacitors) to completely encircle one of the ports reduces the coupling by a noticeable amount over the baseline case. In agreement with the previous results, as the number of unit cells that completely encircle one of the ports increases, the coupling correspondingly decreases compared to the baseline case. In the case of the 5×5 array of capacitors, the coupling level between ports is less than −35 dB for frequencies below 2.5 GHz. The isolation level is less than−50 dB at frequencies below 2.5 GHz for the 7×7 array of capacitors and is 20 dB or more better than the baseline case up to 4 GHz. These results clearly show that the maximum frequency at which the chip capacitors cut off noise is extended from 250 MHz using only 3 capacitors to 4 GHz or greater with localized lattice structures created with SMT capacitors.

Of course, in addition to the arrangements of the patches shown in the previous figures, it is possible to use other arrangements, such as those shown in the patent applications incorporated by reference. Rather than present all of the figures and describe them again, a brief summary of some of the arrangements follows.

Methods of reducing the lower edge of the fundamental stopband for arrays with patches only, one may increase the capacitance of the patches by increasing the dielectric constant of the material between the patches and the conductive surface of the upper layer, increasing the area of the patches, or reducing the thickness between the patches and the conductive surface of the upper layer, increase the height of the PPW, or increase the inductance of the via by decreasing the cross sectional area of the vias. To increase the upper edge of the fundamental stopband one may decrease the period of the array, the effective dielectric constant of the PPW, the inductance of the via by increasing the cross sectional area of the via and/or providing multiple vias for the same patch. Non-planar structures such as those curved in cross section (including coaxial or square cross sections) and non-uniform patches and/or vias may also be used.

Embodiments may be used that adjust the thicknesses and dielectric constants of the dielectric layers, adjust the height of the overall PCB structure, adjust the shapes and sizes of the patches and/or vias, coplanar spirals or meanderlines may be formed to increase the series inductance (L₁) without increasing the period of the array, or multiple levels of capacitive patches may be used to increase the capacitance. The last embodiment may be readily integratable with existing board designs if even numbers of layers of patches are used. This permits addition of an even number of layers to an existing board design and while still maintaining advantages provided by the use of only even numbers of layers in board designs as discussed below.

Note that the geometries and material properties discussed herein and shown in the embodiments of the figures are intended to be illustrative only. Other variations may be readily substituted and combined to achieve particular design goals or accommodate particular materials or manufacturing processes.

The embodiments described here are not limited in their realization to PCBs and low temperature cofired ceramic (LTCC) modules. Depending on the desired stopband frequency, TEM mode suppression circuits may be realized on-chip as part of a semiconductor wafer fabrication. Selection of materials and processes which surround the vias in a low permittivity material and placement of a very high permittivity material between the patches and the nearest conductive plate of the PPW may be used in different designs. Choices for the high permittivity dielectric include ceramic compounds such as Zr_{0.15}Sn_{0.3}Ti_{0.55}O₂ (εᵣ₂˜60), or PbZr_{0.53} Ti_{0.47}O₃ (εᵣ₂˜820), or Ba_{0.15}Sr_{0.85}TiO₃ (εᵣ₂˜400). A good choice for a low permittivity material is SiO₂ (εᵣ₁˜3.9). If the structure is implemented as a part of a semiconductor wafer, conventional materials used in semiconductor processing, such as doped and undoped silicon, silicon dioxide, silicon nitride doped and undoped polysilicon may be used. The various techniques known for modifying electrical parameters of portions of a semiconductor wafer may be used to tailor materials to particular design requirements.

From the foregoing, it can be seen that the present embodiments provide improved circuits, devices and methods for reducing induced power plane noise and improving RF isolation. The devices may be embodied as periodic structures within waveguides capable of supporting TEM mode propagation, or as transverse electromagnetic mode suppression circuits. These embodiments have several distinct advantages over conventional EMI or EMC solutions for instance those using capacitive plane technology also referred to as buried capacitance layers.

The embodiments of the present invention offer significantly more isolation than is attainable from previously known noise suppression circuits. Isolation levels of 70 dB or more are practical between points on a power plane separated by only fractions of an inch. The disclosed embodiments will cut off parallel plate modes that travel in any transverse direction, assuming the power plane is large enough in transverse dimensions to accommodate several periods of cells. These embodiments can readily be designed to have a stopband as low as 50 MHz using conventional PCB materials (2 mil FR4 or prepreg) and processes. Additionally, these embodiments may be lower in PCB fabrication cost than conventional high-impedance surfaces for several reasons. Also the overall thickness of the TEM mode suppression circuits can be reduced with the new structures over conventional structures. In addition, the reduced amount of space used to form the suppression circuits provides much more design flexibility.

It is therefore intended that the foregoing detailed description be regarded as illustrative rather than limiting, and that it be understood that it is the following claims, including all equivalents, that are intended to define the spirit and scope of this invention.

1. A multilayer board comprising:
a central area on a first layer in which an electrical device is to be mounted; and
a localized array of elements at least partially surrounding the central area on the first layer or on a second layer extending parallel to the first layer.

2. The board of claim 1 wherein the elements comprise capacitors formed on the first layer.

3. The board of claim 1 wherein the elements comprise conductive coplanar patches formed on the second layer.

4. The board of claim 3 further comprising a C-plane formed in the central area.

5. The board of claim 4 wherein the C-plane is coplanar with the patches.

6. The board of claim 4 wherein the C-plane is formed on a third layer extending in parallel with the first and second layers.

7. The board of claim 3 wherein the patches are disposed adjacent to a signal line disposed on the second layer.

8. The board of claim 3 wherein a characteristic of the patches in the array changes with distance from the central area.

9. The board of claim 8 wherein the characteristic includes sizes of the patches.

10. The board of claim 8 wherein the characteristic includes shapes of the patches.

12. The board of claim 3 wherein the patches are rectangular.

13. The board of claim 12 wherein the rectangular patches are larger than the electronic device and extend throughout the central area.

14. The board of claim 3 further comprising a ground plane to which the patches are connected through conductive rods.

15. The board of claim 3 wherein the patches are connected to the ground plane through multiple conductive rods.

16. The board of claim 2 wherein the elements comprise conductive coplanar patches formed on the second layer.

17. The board of claim 1 wherein the array completely surrounds the central area.

18. The board of claim 1 wherein the number of elements in the array in the particular direction from the central area is different from the number of elements in the array in at least one direction orthogonal or parallel to the particular direction from the central area.

19. The board of claim 1 wherein the elements have the same characteristics throughout the array.

20. The board of claim 1 wherein multiple arrays are present in the same layer.

21. The board of claim 1 wherein a maximum of 4 elements are in the array in the particular direction.

22. The board of claim 1 wherein the conductive rods are plated through holes.

23. An apparatus for suppressing noise in an electrical device, the apparatus comprising:
a surface on which the electrical device is to be disposed;
a localized array of conductive coplanar patches adjacent to a central area over which the electrical device is to be disposed;
a first conductive layer;
a first dielectric layer disposed between the patches and the first conductive layer;
a second dielectric layer disposed between the patches and the surface; and
conductive vias extending through the first dielectric layer connecting the patches with the first conductive layer.

24. The apparatus of claim 23 wherein multiple localized arrays are arranged between the first and second dielectric layers.

25. The apparatus of claim 23 wherein the patches terminate at least one patch length from an edge of the first dielectric layer in multiple orthogonal directions.

26. The apparatus of claim 23 wherein the patches completely encircle the central area.

27. The apparatus of claim 23 wherein the patches do not completely encircle the central area.

28. The apparatus of claim 23 wherein a C-plane is disposed in the central area.

29. The apparatus of claim 23 wherein a characteristic of the patches extending from the central area in different directions are different.

30. The apparatus of claim 23 further comprising a localized array of chip capacitors disposed on the surface, the chip capacitors connected to the patches through the conductive rods, which extend through the second dielectric layer.

31. The apparatus of claim 30 wherein each patch is connected to an associated chip capacitor.

32. The apparatus of claim 23 wherein only a minimum number of patches is provided between the central area and a location on an opposite side of the localized array to provide a desired amount of attenuation of electromagnetic radiation of a desired frequency range emanating from the electrical device in a direction between the central area and the location.

33. A printed circuit board (PCB) comprising:
opposing outermost surfaces containing signal lines;
an array of conductive coplanar patches disposed between the surfaces;
a first conductive layer;
a first dielectric layer disposed between the patches and the first conductive layer;
a second conductive layer having a different potential than the first conductive layer;
a second dielectric layer disposed between the patches and the second conductive layer; and
conductive rods extending through the first dielectric layer connecting the patches with the first conductive layer such that the patches are at the same potential as the first conductive layer and the second conductive layer is more proximate to the patches than the first conductive layer.

34. The PCB of claim 33 wherein the patches are disposed closer to the second conductive layer than any other non-dielectric layer.

35. The PCB of claim 33 further comprising:
a third conductive layer disposed on an opposite side of the second conductive layer as the patches; and
a third dielectric layer disposed between the second and third conductive layers.

36. The PCB of claim 35 wherein the first and third conductive layers are more proximate to the outermost surfaces than any other conductive layer.

37. The PCB of claim 35 wherein the first and third conductive layers are at the same potential.

38. The PCB of claim 37 wherein the first and third conductive layers are grounded.

39. The PCB of claim 33 further comprising an inner layer on which signal lines are arranged, the inner layer disposed between the first and second conductive layers, wherein the patches are disposed on the inner layer.

40. The PCB of claim 39 further comprising another first conductive layer, another inner layer containing signal lines and an array of patches connected with the other first conductive layer, and another second conductive layer at a different potential from the other first conductive layer, wherein the other first conductive layer, the other inner layer, and the other second conductive layer are disposed substantially mirror image around a center of the PCB from the first conductive layer, the inner layer, and the second conductive layer, respectively.

41. The PCB of claim 33 further comprising an inner layer on which signal lines are arranged, the inner layer disposed between the first conductive layer and the patches, wherein the conductive rods extend through the inner layer without contacting the signal lines.

42. The PCB of claim 41 further comprising another first conductive layer, another inner layer containing signal lines, another array of patches connected with the other first conductive layer, and another second conductive layer at a different potential from the other first conductive layer, wherein the other first conductive layer, the other inner layer, the other array of patches and the other second conductive layer are disposed substantially mirror image around a center of the PCB from the first conductive layer, the inner layer, the localized array of patches, and the second conductive layer, respectively.

43. The PCB of claim 41 wherein the patches are disposed closer to the second conductive layer than any other non-dielectric layer.

44. The PCB of claim 33 further comprising:
a third conductive layer disposed on an opposite side of the first conductive layer as the patches; and
an inner layer on which signal lines are arranged, the inner layer disposed between the first and third conductive layers.

45. The PCB of claim 44 wherein the first and third conductive layers are at the same potential.

46. The PCB of claim 45 wherein the first and third conductive layers are grounded.

47. The PCB of claim 44 further comprising another first conductive layer, another inner layer containing signal lines, another array of patches connected with the other first conductive layer, another second conductive layer at a different potential from the other first conductive layer, and another third conductive layer, wherein the other first conductive layer, the other inner layer, the other array of patches, the other second conductive layer and the other third conductive layer are disposed substantially mirror image around a center of the PCB from the first conductive layer, the inner layer, the localized array of patches, the second conductive layer and the third conductive layer, respectively.

48. The PCB of claim 44 wherein the patches are disposed closer to the second conductive layer than any other non-dielectric layer.

49. The PCB of claim 33 further comprising a plurality of inner layers on which signal lines are arranged, the inner layer disposed between the first and second conductive layers.

50. The PCB of claim 49 wherein the patches are disposed on one of the inner layers.

51. The PCB of claim 49 wherein the inner layers are disposed between the first conductive layer and the patches, the conductive rods extend through the inner layers without contacting the signal lines.

52. The PCB of claim 49 wherein the patches are disposed closer to the second conductive layer than any other non-dielectric layer.

53. The PCB of claim 33 wherein at least one of the first and second conductive layers are split into coplanar split portions such that different potentials are applied to the split portions.

54. The PCB of claim 33 wherein the first conductive layer is a power plane and the second conductive layer is a ground plane.

55. The PCB of claim 33 wherein the patches are coplanar with a C-plane.

56. The PCB of claim 33 wherein the patches are formed in a localized array arranged such that the patches in the array cover an area substantially less than that of the PCB

57. A method of attenuating electromagnetic radiation in a particular direction along a printed circuit board (PCB), the method comprising providing a localized array of elements between two coplanar locations of the PCB and limiting a number of unit cells of the array to substantially fewer than a number of unit cells to cover an entire distance between the coplanar locations.

58. The method of claim 57 wherein the elements comprise conductive coplanar patches between surfaces of the PCB.

59. The method of claim 58 further comprising providing a C-plane that is coplanar with the patches.

60. The method of claim 57 wherein the elements comprise chip capacitors disposed on a surface of the PCB.
